(19) United States
(12) Patent Application Publication
(10) Pub. No.: US 2013/0247982 A1
(43) Pub. Date: Sep. 26, 2013

(54) SOLAR CELL

(71) Applicants: Eun Cheol Do, Yongin-si (KR); Dong Kyun Kim, Suwon-si (KR); Yun Gi Kim, Yongin-si (KR); Chul Ki Kim, Yongin-si (KR); Yeon il Lee, Seoul (KR); Young Moon Choi, Seoul (KR)

(72) Inventors: Eun Cheol Do, Yongin-si (KR); Dong Kyun Kim, Suwon-si (KR); Yun Gi Kim, Yongin-si (KR); Chul Ki Kim, Yongin-si (KR); Yeon il Lee, Seoul (KR); Young Moon Choi, Seoul (KR)

(73) Assignee: SAMSUNG ELECTRONICS CO., LTD., Suwon-si (KR)

(21) Appl. No.: 13/531,728

(22) Filed: Jun. 25, 2012

(30) Foreign Application Priority Data
Mar. 22, 2012 (KR) 10-2012-0029554

(51) Int. Cl. H01L 31/0232; H01L 31/0264

(52) U.S. Cl. 136/259; 136/252; 136/261

(57) ABSTRACT

A solar cell may include a PN junction including a semiconductor substrate of a first conductivity and an emitter of a second conductivity, a passivation layer on an exposed surface of the semiconductor substrate, a first electrode connected to the semiconductor substrate, and a second electrode connected to the emitter. The passivation layer may be configured to apply stress to the exposed surface of the substrate such that a mobility of minority charge carriers in the semiconductor substrate is decreased in a first direction perpendicular to a boundary surface of the semiconductor substrate and the passivation layer.

### CROSS-REFERENCE TO RELATED APPLICATIONS

This application claims priority to and the benefit of Korean Patent Application No. 10-2012-0029554 filed in the Korean Intellectual Property Office on Mar. 22, 2012, the entire contents of which are incorporated herein by reference.

### BACKGROUND

1. Field

Example embodiments provide a solar cell.

2. Description of the Related Art

Primary energy sources currently used for humankind are fossil fuels, e.g., coals and petroleum. However, fossil fuels are being exhausted and cause global warming and environmental pollution. Solar light, tidal power, wind power, and/or geothermal heat are being studied as an alternative energy source for replacing fossil fuel.

Among them, a solar cell technology of converting solar light into electricity utilizes a material that produces holes and electrons to generate currents upon receipt of light. However, the efficiency of the solar cell may be insufficient due to the hole-electron recombination at a surface of a layer or a film in the solar cell.

### SUMMARY

According to example embodiments, a solar cell may include a PN junction including a semiconductor substrate of a first conductivity and an emitter of a second conductivity, a passivation layer on an exposed surface of the semiconductor substrate, a first electrode connected to the semiconductor substrate, and a second electrode connected to the emitter. The passivation layer may be configured to apply stress to the exposed surface of the substrate such that a mobility of minority charge carriers in the semiconductor substrate is decreased in a first direction perpendicular to a boundary surface of the semiconductor substrate and the passivation layer.

The first conductivity may be P-type, the second conductivity is N-type, and the passivation layer is configured to apply a tensile stress in the first direction to the exposed surface of the semiconductor substrate. The passivation layer may be configured to absorb a compressive stress in the first direction. The tensile stress in the first direction applied to the exposed surface of the semiconductor substrate by the passivation layer may have a value equal to or less than −800 MPa.

The passivation layer may include at least one of a thermal oxide, an oxide formed by plasma enhanced chemical vapor deposition (PECVD), a SiN layer formed by low pressure chemical vapor deposition (LPCVD), and a SiN layer formed by PECVD.

The first conductivity may be N-type, the second conductivity may be P-type, and the passivation layer may be configured to apply a compressive stress in the first direction to the exposed surface of the semiconductor substrate. The passivation layer may be configured to absorb a tensile stress in the first direction. The compressive stress in the first direction applied to the exposed surface of the semiconductor substrate by the passivation layer may have a value equal to or less than 4,000 MPa.

The passivation layer includes at least one of an Al₂O₃ layer formed by atomic layer deposition (ALD) and a SiN layer formed by plasma enhanced chemical vapor deposition(PECVD).

The substrate may include single crystalline silicon, and the passivation layer may include at least one of an oxide, a nitride, amorphous silicon, ZnS and Mg F₂.

An anti-reflection coating may be on an exposed surface of the emitter. The first electrode and the second electrode may be on opposite sides of the PN junction. The first electrode and the second electrode may be on a same side of the PN junction.

The anti-reflection coating may include at least one of MgF₂, ZnS, SiNₓ, SiO₂, and Al₂O₃. The first electrode and the second electrode may include at least one of a metal and a transparent conducting oxide (TOO). The metal may include one of Al, Ag, Au, and Cu. The thicknesses of the semiconductor substrate, the emitter, the passivation layer, and the anti-reflection coating may be about 1 um to about 500um, about 0.1um to about 10um, about 5 nm to about 500 nm, and about 5 nm to about 500 nm, respectively.

### BRIEF DESCRIPTION OF THE DRAWINGS

Example embodiments will be more clearly understood from the following detailed description taken in conjunction with the accompanying drawings. FIGS. 1-9 represent non-limiting, example embodiments as described herein.

FIG. 1 is a schematic sectional view of a solar cell according to example embodiments.

FIGS. 2 and 3 are perspective views schematically showing stress applied on a passivation layer of a solar cell according to example embodiments.

FIGS. 4 and 5 are perspective views schematically showing stress applied on a substrate and a passivation layer of a solar cell according to example embodiments.

FIG. 6 is a graph showing the efficiency of a solar cell including a P-type substrate as function of strength of a vertical stress on the substrate.

FIG. 7 is a graph showing the efficiency of a solar cell including an N-type substrate as function of strength of a vertical stress on the substrate.

FIGS. 8 and 9 are schematic sectional views of solar cells according to example embodiments.

### DETAILED DESCRIPTION

Example embodiments will be described more fully hereinafter with reference to the accompanying drawings. As those skilled in the art would realize, the described embodiments may be modified in various different ways, all without departing from the spirit or scope. In the drawings, parts having no relationship with the explanation are omitted for clarity, and the same or similar reference numerals designate the same or similar elements throughout the specification.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

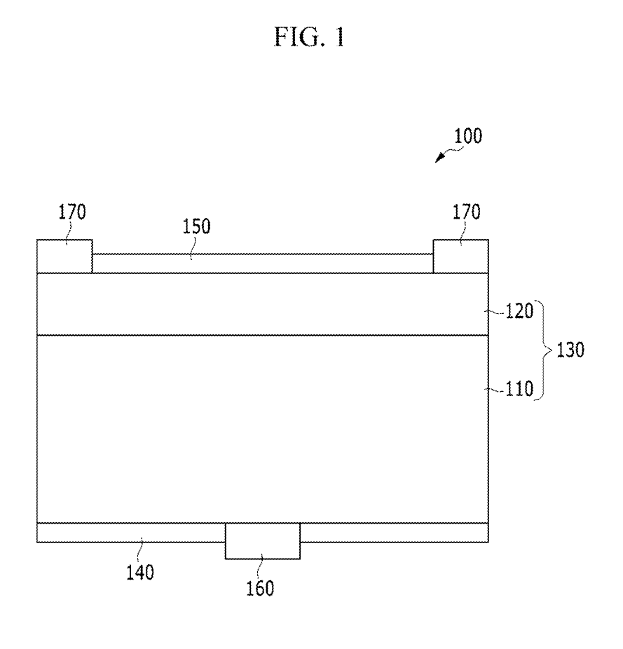

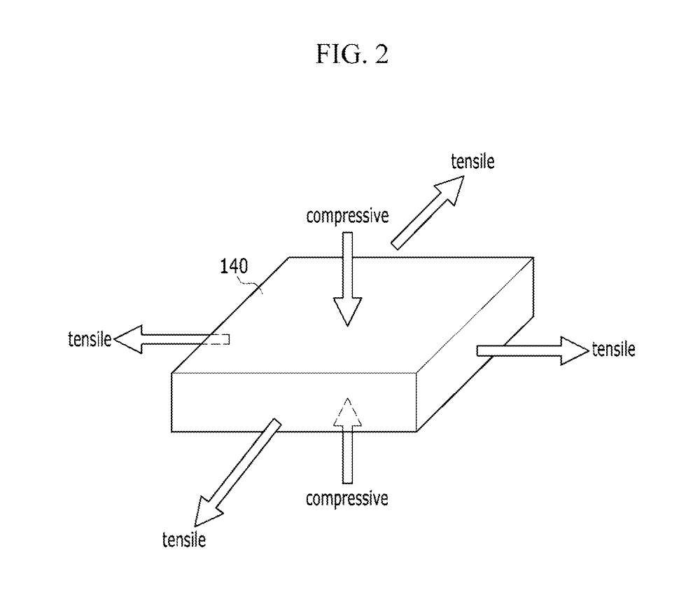

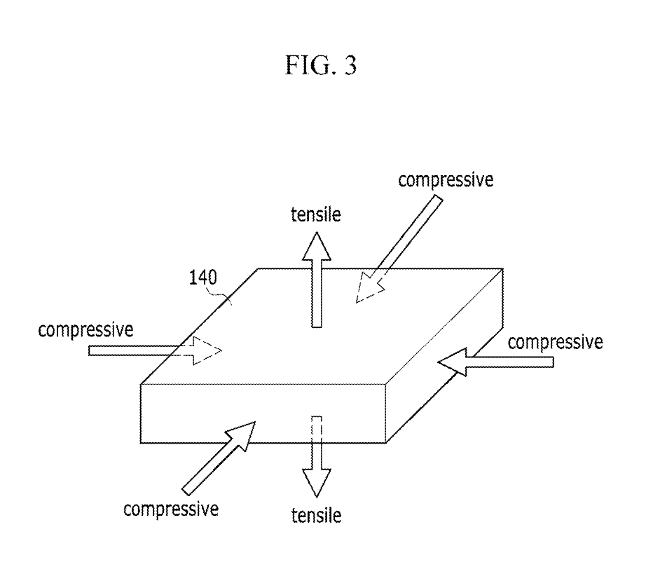

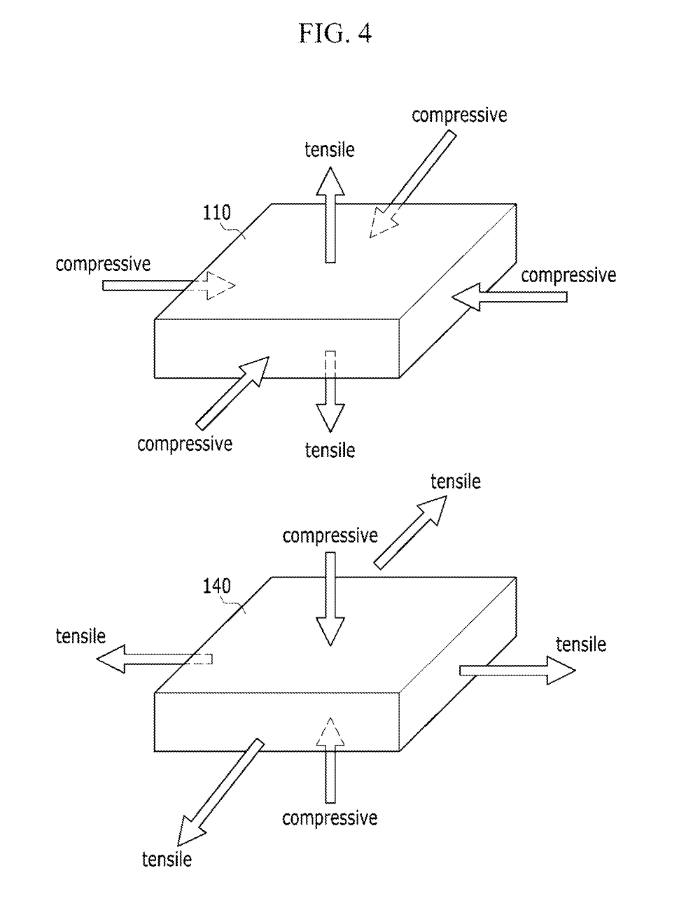

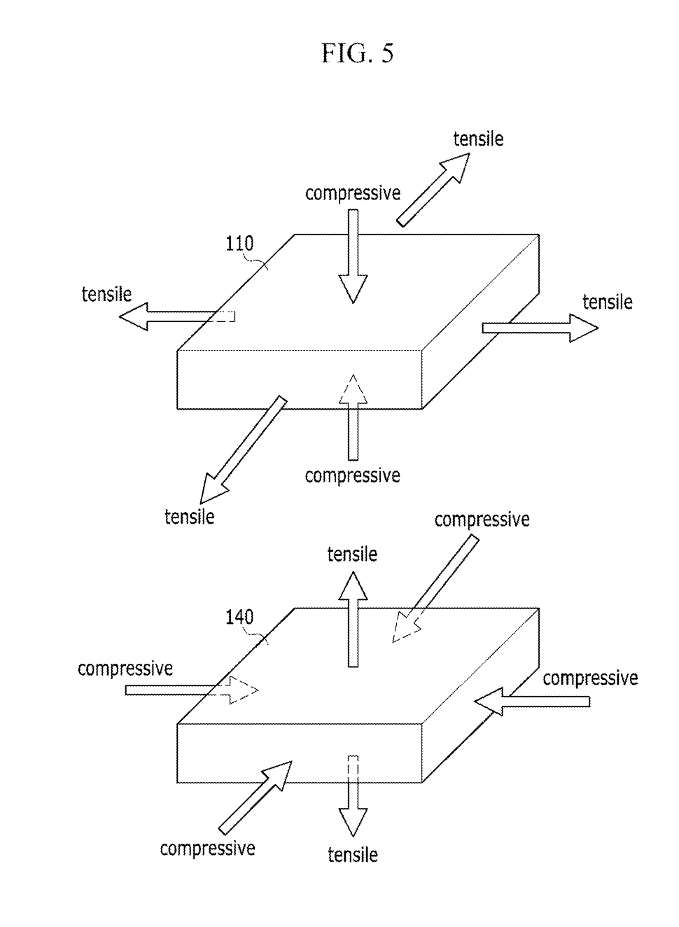

A solar cell according to example embodiments is described in detail with reference to FIGS. 1 to 5. FIG. 1 is a schematic sectional view of a solar cell according to example embodiments, FIGS. 2 and 3 are perspective views schematically showing stress applied on a passivation layer of a solar cell according to example embodiments, and FIGS. 4 and 5 are perspective views schematically showing stress applied on a substrate and a passivation layer of a solar cell according to example embodiments.

Referring to FIG. 1, a solar cell 100 according to example embodiments includes a semiconductor substrate 110, an emitter 120, a passivation layer 140, an anti-reflection coating 150, a substrate electrode 160, and an emitter electrode 170.

The semiconductor substrate 110 and the emitter 120 have opposite conductivities and are in contact with each other to form a PN junction 130. For example, when the semiconductor substrate 110 is P-type, the emitter 120 is N-type. On the contrary, when the semiconductor substrate 110 is N-type, the emitter 120 is P-type.

The semiconductor substrate 110 may be a single crystalline silicon substrate, and the emitter 120 may be formed by implanting an impurity into the substrate 110 having a conductivity opposite a conductivity of the substrate 110.

The passivation layer 140 contacts a substrate-side surface of the PN junction 130 and covers a surface of the substrate 110 to be protected. The passivation layer 140 is configured to suffer compressive or tensile stress in a direction (referred to as “a horizontal direction” hereinafter) substantially parallel to a boundary surface between the substrate 110 and the passivation layer 140.

When a type of stress in the horizontal direction is applied to the passivation layer 140, an opposite type of stress may be applied in a direction (referred to as “a vertical direction” hereinafter) substantially perpendicular to the boundary surface between the substrate 110 and the passivation layer.

Referring to FIG. 2, a tensile stress applied on the passivation layer 140 in the horizontal direction may cause a compressive stress applied on the passivation layer in the vertical direction, and, on the contrary, a compressive stress in the vertical direction may cause a tensile stress in the horizontal direction. Referring to FIG. 3, a compressive stress applied on the passivation layer 140 in the horizontal direction may cause a tensile stress applied on the passivation layer in the vertical direction, and, on the contrary, a tensile stress in the vertical direction may cause a compressive stress in the horizontal direction. Accordingly, the passivation layer 140 may be configured to suffer a tensile stress in the vertical direction, or a compressive stress in the horizontal direction.

The type of the stress on the passivation layer 140 may depend on the conductivity of the substrate 110. For example, a vertical stress on the passivation layer 140 may be compressive for the substrate 110 with a P-type conductivity, while a vertical stress on the passivation layer 140 may be tensile for the substrate 110 with an N-type conductivity.

Examples of the passivation layer 140 may include oxides, e.g., SiO₂ and Al₂O₃, nitrides, e.g., SiNₓ, amorphous silicon, ZnS, MgF₂, or combinations thereof. When the passivation layer 140 includes a nitride, ZnS, or MgF₂, the passivation layer 140 may prevent or inhibit light reflection as well as protect the surface of the substrate 110.

The anti-reflection coating 150 may be disposed on an emitter-side surface of the PN junction 130 and may prevent or inhibit the reflection of incident light to improve the efficiency of the solar cell 100. The anti-reflection coating 150 may also cover and protect the emitter-side surface of the PN junction 130. Examples of the anti-reflection coating 150 may include at least one of MgF₂, ZnS, SiNₓ, SiO₂, and Al₂O₃. The anti-reflection coating 150 may be omitted.

The substrate electrode 160 may be connected to the substrate 110 through a contact hole in the passivation layer 140, and the emitter electrode 170 may be connected to the emitter 120 through a contact hole in the anti-reflection coating 150. Materials for the electrodes 160 and 170 may include, for example, at least one of metals, e.g., Al, Ag, Au, and Cu or at least one of transparent conducting oxides (TCO).

The thicknesses of the substrate 110, the emitter 120, the passivation layer 140, and the anti-reflection coating 150 may be about 1 um to about 500 um, about 0.1 um to about 10 um, about 5 nm to about 500 nm, and about 5 nm to about 500 nm, respectively.

When the solar cell 100 receives solar light, charge carriers, e.g., holes and electrons, may be produced in the PN junction 130 and move to the electrodes 160 and 170 such that currents flow outward through the electrodes 160 and 170.

The charge carriers, e.g., majority charge carriers and/or minority charge carriers, produced in the substrate 110 may gather near the boundary surface between the substrate 110 and the passivation layer 140. Therefore, the gathered charge carriers may recombine with each other near the boundary surface between the substrate 110 and the passivation layer 140, and their recombination may decrease the efficiency of the solar cell 100. The majority charge carriers are holes and the minority charge carriers are electrons when the substrate 110 has a P-type conductivity, and vice versa for the substrate 110 with an N-type conductivity.

According to example embodiments, the passivation layer 140, which may suffer stress by itself, may apply vertical and horizontal stress on at least a portion of the substrate 110, for example, a portion disposed near the boundary surface between the substrate 110 and the passivation layer 140. The stress suffered by the substrate 110 may be a type opposite to a type of stress suffered by the passivation layer 140.

As described above, the passivation layer 140 may be configured to suffer a tensile stress in the horizontal direction when the substrate 110 has a P-type conductivity, for example. Referring to FIG. 4, when a tensile stress in the horizontal direction is applied on the passivation layer 140, a tensile stress in the vertical direction and a compressive stress in the horizontal direction may be applied on the substrate 110. A vertical tensile stress applied to the substrate 110 with a P-type conductivity may cause decrease of electron mobility and increase of hole mobility in the vertical direction. The number of the minority charge carriers, e.g., the number of electrons that reach the boundary surface of the substrate 110 and the passivation layer 140, may be reduced so that the hole-electron recombination may be decreased.

On the contrary, when the substrate 110 has an N-type conductivity, the passivation layer 140 may be configured to suffer a horizontal compressive stress. Referring to FIG. 5, the stresses applied to the substrate 110 with the N-type conductivity may be tensile in the horizontal direction and may be compressive in the vertical direction. In example embodiments, because hole mobility may be decreased and electron mobility may be increased in the vertical direction in the substrate 110 with the N-type conductivity, the number of the minority charge carriers, e.g., the number of holes that reach the boundary surface of the substrate 110 and the passivation layer 140, and thus the hole-electron recombination, may be decreased.

As described above, example embodiments provide the passivation layer 140 that is configured to differentiate the type of stress depending on the conductivity of the substrate 110. Accordingly, the number of the minority charge carriers that reach the boundary surface of the substrate 110 and the passivation layer 140 may be reduced, and thus, the recombination of the majority charge carriers and the minority charge carriers may be reduced to increase the efficiency of the solar cell 100.

In order to obtain a desired type of stress applied to the passivation layer 140, the size of the lattice of the passivation layer 140 may be adjusted. For example, when the lattice of the passivation layer 140 is larger than the lattice of the substrate 110, a vertical stress applied to the substrate 110 by the passivation layer 140 may be compressive. On the contrary, the passivation layer 140 with the lattice smaller than the lattice of the substrate 110 may apply a tensile vertical stress to the substrate 110.

When the passivation layer 140 is an oxide formed by thermal oxidation or plasma enhanced chemical vapor deposition (PECVD), a horizontal stress suffered by the passivation layer 140 may be a compressive stress of about 350 MPa to about 400 MPa. When the passivation layer 140 is a SiN layer formed by low pressure chemical vapor deposition (LPCVD), a horizontal stress suffered by the passivation layer 140 may be a compressive stress of about 700 MPa to about 1200 MPa. In contrast, when the passivation layer 140 is a SiN layer formed by PECVD, a horizontal stress suffered by the passivation layer 140 may have a strength of about −300 MPa to about 850 MPa, and may be tensile or compressive. When the passivation layer 140 is an Al₂O₃ layer formed by atomic layer deposition (ALD), the stress suffered by the passivation layer 140 may be a tensile stress of about −300 MPa to about −1.3 GPa.

The strength of the stress suffered by the passivation layer 140, or the strength of the stress applied to the substrate 110 by the passivation layer 140 may vary depending on a process condition. The strength of the stress may become as high as the deposition temperature is low. As the heat treatment is performed, the film thickness may become larger. When the passivation layer 140 is formed by depositing SiN using PECVD, the stress strength may vary depending on one of temperature and RF frequency. Thus, the passivation layer 140 with a desired type of stress may be obtained by adjusting one of temperature and RF frequency.

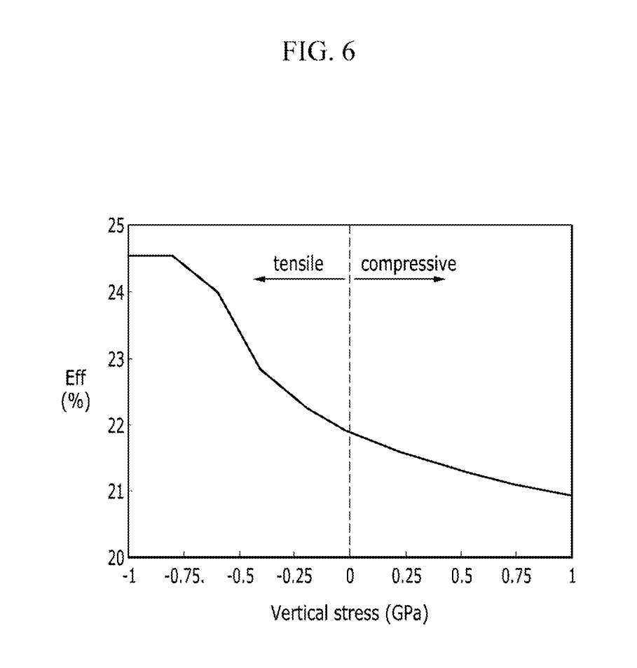

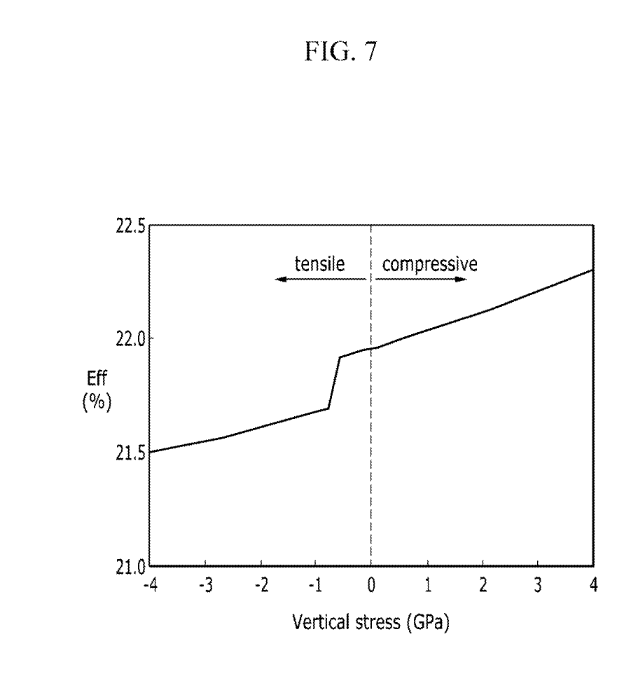

Characteristics of an experimental solar cell are described in detail with reference to FIGS. 6 and 7.

FIG. 6 is a graph showing the efficiency of a solar cell including a P-type substrate as function of strength of a vertical stress on the substrate, and FIG. 7 is a graph showing the efficiency of a solar cell including an N-type substrate as function of strength of a vertical stress on the substrate.

In a solar cell 100 having a structure shown in FIG. 1, a stress that a passivation layer 140 applies to a surface of a substrate 110 was varied, and short-circuit current density (JSC), open-circuit voltage (VOC), fill factor (FF), and efficiency (Eff) were calculated by using Synopsys Technology Computer-Aided Design (TCAD) computer simulation.

First, a result of a simulation for a solar cell 100 with a P-type substrate 110 and an N-type emitter 120 is shown in Table 1 and FIG. 6.

TABLE 1

| Vertical Stress | Horizontal Stress | | | | |
|---|---|---|---|---|---|
| (MPa) | (MPA) | Jsc | Voc | FF | Eff |
| 1000 | −500 | 40.25 | 0.629 | 82.64 | 20.93 |
| 800 | −400 | 40.37 | 0.631 | 82.65 | 21.06 |
| 600 | −300 | 40.51 | 0.633 | 82.71 | 21.21 |
| 400 | −200 | 40.67 | 0.636 | 82.75 | 21.39 |
| 200 | −100 | 40.85 | 0.639 | 82.82 | 21.61 |
| 0 | 0 | 41.06 | 0.643 | 82.89 | 21.88 |
| −200 | 100 | 41.31 | 0.649 | 83.01 | 22.26 |
| −400 | 200 | 41.62 | 0.660 | 83.17 | 22.83 |
| −600 | 300 | 42.01 | 0.685 | 83.49 | 24.01 |
| −800 | 400 | 42.08 | 0.699 | 83.49 | 24.55 |
| −1000 | 500 | 42.08 | 0.699 | 83.49 | 24.55 |

Referring to Table 1 and FIG. 6, when the substrate 110 has a P-type conductivity, the solar cell 100 without stress on the substrate 110 shows an efficiency of about 21.88%. The efficiency Eff becomes higher as the vertical stress on the substrate 110 becomes more tensile. For example, the efficiency EFF for the stress equal to or smaller than about −800 MPa is about 24.55%, which is higher by about 2.67% compared with the case without stress. On the contrary, the efficiency Eff becomes lower as the vertical stress on the substrate 110 is more compressive.

A result of a simulation for a solar cell 100 with an N-type substrate 110 and a P-type emitter 120 is shown in Table 2 and FIG. 7.

TABLE 2

| Vertical Stress | Horizontal Stress | | | | |
|---|---|---|---|---|---|
| (MPa) | (MPa) | Jsc | Voc | FF | Eff |
| 4000 | −2000 | 40.76 | 0.661 | 82.81 | 22.31 |
| 2000 | −1000 | 40.59 | 0.659 | 82.76 | 22.12 |
| 1000 | −500 | 40.52 | 0.657 | 82.74 | 22.04 |
| 600 | −300 | 40.49 | 0.657 | 82.73 | 22.01 |
| 200 | −100 | 40.46 | 0.657 | 82.72 | 21.97 |
| 0 | 0 | 40.44 | 0.656 | 82.71 | 21.96 |
| −200 | 100 | 40.43 | 0.656 | 82.71 | 21.95 |
| −600 | 300 | 40.40 | 0.656 | 82.71 | 21.92 |
| −1000 | 500 | 40.70 | 0.648 | 82.23 | 21.68 |
| −2000 | 1000 | 40.64 | 0.647 | 82.21 | 21.61 |
| −4000 | 2000 | 40.53 | 0.645 | 82.22 | 21.5 |

Referring to Table 2 and FIG. 7, when the substrate 110 has an N-type conductivity, the solar cell 100 without stress on the substrate 110 shows an efficiency of about 21.96%. The efficiency Eff becomes higher as the vertical stress on the substrate 110 becomes more compressive. For example, the efficiency EFF for the stress equal to or smaller than about 4000 MPa is about 22.31%. On the contrary, the efficiency Eff becomes lower as the vertical stress on the substrate 110 is more tensile.

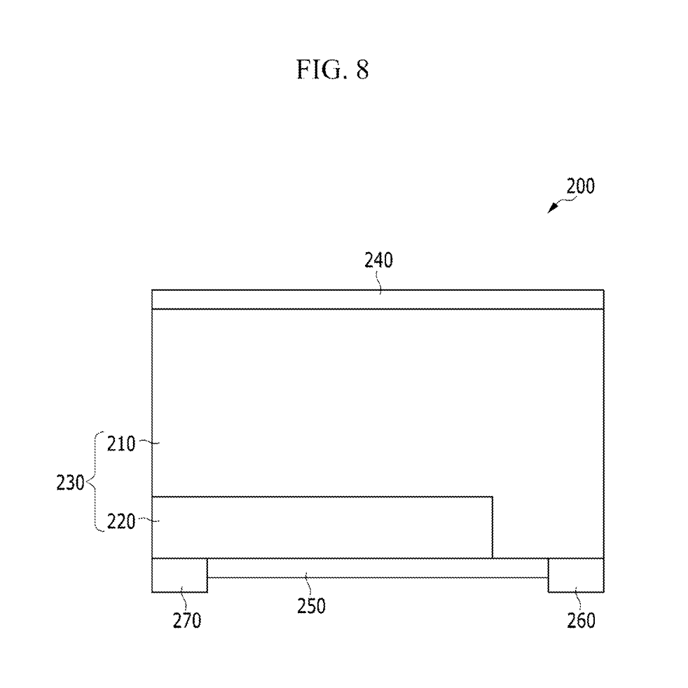

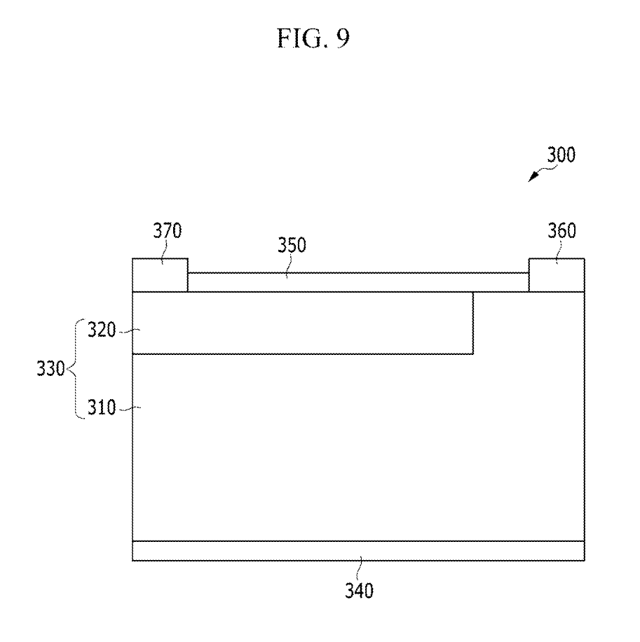

FIGS. 8 and 9 are schematic sectional views of solar cells according to example embodiments. A solar cell 200 shown in FIG. 8 includes a PN junction 230, a passivation layer 240, an anti-reflection coating 250, a substrate electrode 260, and an emitter electrode 270. The detailed descriptions of each portion of the solar cell 200 may be omitted because the structure of the solar cell 200 is similar to the solar cell 100 shown in FIG. 1, and features of the solar cell 200 distinguished from the solar cell 100 shown in FIG. 1 are mainly described.

The PN junction 230 includes a substrate 210 and an emitter 220 that have different conductivities, like FIG. 1. However, the emitter 220 is disposed under the substrate 210 according to example embodiments as illustrated in FIG. 8 while the emitter 120 is disposed on the substrate 110 in FIG. 1.

The vertical positional relationship of the substrate 210 and the emitter 220 in the solar cell 200 shown in FIG. 8, which is the reverse of the vertical positional relationship of the substrate 110 and the emitter 120 in the solar cell 100 shown in FIG. 1, causes a reversed positional relationship between the passivation layer 240 and the anti-reflection coating 250 in the solar cell 200 shown in FIG. 8 compared with the solar cell 100 shown in FIG. 1. In detail, the passivation layer 240 is disposed on a top surface of the PN junction 230, and the anti-reflection coating 250 is disposed under a bottom surface of the PN junction 230 in example embodiments as shown in FIG. 8.

In addition, the substrate electrode 260 and the emitter electrode 270 in FIG. 8 are disposed at the same side of the PN junction 230 while the substrate electrode 160 and the emitter electrode 170 are disposed opposite each other as shown in FIG. 1. In order to obtain the structure where the electrodes 260 and 270 are at the same side, both the substrate 210 and the emitter 220 may be exposed at a surface of the PN junction 230. In detail, a portion of a bottom surface of the substrate 210 is covered by the emitter 220 and another portion of the bottom surface of the substrate 210 is not covered by the emitter 220 to be exposed in example embodiments as shown in FIG. 8 while the emitter 120 covers an entire surface of the substrate 110 as shown in FIG. 1.

When the electrodes 260 and 270 are disposed under the PN junction 230 as shown in FIG. 8, the area exposed to incident light is relatively wide, and thus the efficiency may be relatively high.

A solar cell 300 shown in FIG. 9 includes a PN junction 330, a passivation layer 340, an anti-reflection coating 350, a substrate electrode 360, and an emitter electrode 370. The detailed descriptions of each portion of the solar cell 300 may be omitted since the structure of the solar cell 300 is similar to the solar cell 100 shown in FIG. 1, and features of the solar cell 300 distinguished from the solar cell 100 shown in FIG. 1 are mainly described.

The PN junction 330 includes a substrate 310 and an emitter 320 that have different conductivities, and the emitter 320 is disposed on the substrate 310, similar to example embodiments as shown in FIG. 1. However, both the substrate electrode 360 and the emitter electrode 370 in FIG. 8 are disposed on the top surface of the PN junction 330 while the substrate electrode 160 and the emitter electrode 170 are disposed opposite each other as shown in FIG. 1, and both the substrate 310 and the emitter 320 are exposed at the top surface of the PN junction 330. In detail, a portion of a top surface of the substrate 310 is covered by the emitter 320 and another portion of the top surface of the substrate 310 is not covered by the emitter 320 to be exposed in example embodiments as shown in FIG. 9 while the emitter 120 covers an entire surface of the substrate 110 as shown in FIG. 1.

While this disclosure has been described in connection with what is presently considered to be practical example embodiments, it is to be understood that the invention is not limited to the disclosed embodiments, but, on the contrary, is intended to cover various modifications and equivalent arrangements included within the spirit and scope of the appended claims.

What is claimed is:

1. A solar cell comprising:
a PN junction including a semiconductor substrate of a first conductivity and an emitter of a second conductivity;
a passivation layer on an exposed surface of the semiconductor substrate;
a first electrode connected to the semiconductor substrate; and
a second electrode connected to the emitter,
wherein the passivation layer is configured to apply stress to the exposed surface of the substrate such that a mobility of minority charge carriers in the semiconductor substrate is decreased in a first direction perpendicular to a boundary surface of the semiconductor substrate and the passivation layer.

2. The solar cell of claim 1, wherein the first conductivity is P-type, the second conductivity is N-type, and the passivation layer is configured to apply a tensile stress in the first direction to the exposed surface of the semiconductor substrate.

3. The solar cell of claim 2, wherein the passivation layer is configured to absorb a compressive stress in the first direction.

4. The solar cell of claim 3, wherein the tensile stress in the first direction applied to the exposed surface of the semiconductor substrate by the passivation layer has a value equal to or less than −800 MPa.

5. The solar cell of claim 3, wherein the passivation layer includes at least one of a thermal oxide, an oxide formed by plasma enhanced chemical vapor deposition (PECVD), a SiN layer formed by low pressure chemical vapor deposition (LPCVD), and a SiN layer formed by PECVD.

6. The solar cell of claim 1, wherein the first conductivity is N-type, the second conductivity is P-type, and the passivation layer is configured to apply a compressive stress in the first direction to the exposed surface of the semiconductor substrate.

7. The solar cell of claim 6, wherein the passivation layer is configured to absorb a tensile stress in the first direction.

8. The solar cell of claim 7, wherein the compressive stress in the first direction applied to the exposed surface of the semiconductor substrate by the passivation layer has a value equal to or less than 4,000 MPa.

9. The solar cell of claim 7, wherein the passivation layer includes at least one of an Al₂O₃ layer formed by atomic layer deposition (ALD) and a SiN layer formed by plasma enhanced chemical vapor deposition (PECVD).

10. The solar cell of claim 1, wherein the substrate includes single crystalline silicon, and the passivation layer includes at least one of an oxide, a nitride, amorphous silicon, ZnS and MgF₂.

11. The solar cell of claim 1, further comprising:
an anti-reflection coating on an exposed surface of the emitter.

12. The solar cell of claim 11, wherein the first electrode and the second electrode are on opposite sides of the PN junction.

13. The solar cell of claim 11, wherein the first electrode and the second electrode are on a same side of the PN junction.

14. The solar cell of claim 11, wherein the anti-reflection coating includes at least one of MgF₂, ZnS, SiNₓ, SiO₂, and Al₂O₃.

15. The solar cell of claim 1, wherein the first electrode and the second electrode include at least one of a metal and a transparent conducting oxide (TOO).

16. The solar cell of claim 15, wherein the metal includes one of Al, Ag, Au, and Cu.

17. The solar cell of claim 11, wherein the thicknesses of the semiconductor substrate, the emitter, the passivation layer, and the anti-reflection coating is about 1 um to about 500 um, about 0.1 um to about 10 um, about 5 nm to about 500 nm, and about 5 nm to about 500 nm, respectively.
